(19) United States
(12) Patent Application Publication
(10) Pub. No.: US 2025/0037974 A1
(43) Pub. Date: Jan. 30, 2025

(54) CHAMBER FOR SUBSTRATE BACKSIDE AND BEVEL DEPOSITION

(71) Applicant: Applied Materials, Inc., Santa Clara, CA (US)

(72) Inventors: Dmitry LUBOMIRSKY, Cupertino, CA (US); Junghoon KIM, Santa Clara, CA (US); Hyun Joo LEE, Santa Clara, CA (US); Pranav Vijay GADRE, Santa Clara, CA (US); Adib KHAN, Santa Clara, CA (US); Nithin Thomas ALEX, Bangalore (IN); Douglas A. BUCHBERGER, Jr., Livermore, CA (US); Qiwei LIANG, Fremont, CA (US); Ellie Y. YIEH, San Jose, CA (US); Shekhar ATHANI, Bangalore (IN)

(73) Assignee: Applied Materials, Inc., Santa Clara, CA (US)

(21) Appl. No.: 18/227,226

(22) Filed: Jul. 27, 2023

(51) Int. Cl. H01J 37/32

(52) U.S. Cl. CPC H01J 37/32403; H01J 37/32357; H01J 37/32522; H01J 37/32715; H01J 2237/20235; H01J 2237/332

(57) ABSTRACT

Disclosed herein is a processing system. The processing system has an upper chamber body and a lower chamber body defining a processing environment. An upper heater is moveably disposed in the upper chamber body. The upper heater has a moveable support and an upper step formed along an outer perimeter. A lower showerhead is fixedly disposed in the lower chamber body. The lower showerhead includes a top surface configured to support a substrate, a lower step disposed along an outer perimeter wherein the substrate is configured to extend from the top surface partially over the lower step. Lift pins are disposed in the lower showerhead and configured to extend through the top surface and support the substrate thereon. Gas holes are disposed in a first zone along the top surface and a second zone on the step and configured to independently flow both a process and non-process gas.

### BACKGROUND

### Field

Embodiments of the present disclosure generally relate to methods and apparatus for processing a substrate. More specifically, the disclosure is directed towards methods and apparatus for deposition or etch of a backside and/or bevel edge of a substrate.

### Description of the Related Art

The fabrication of microelectronic devices typically involves a complicated process sequence requiring hundreds of individual processes performed on semi-conductive, dielectric, and conductive substrates. Examples of these processes include oxidation, diffusion, ion implantation, thin film deposition, cleaning, etching, and lithography, among other operations. Each operation is time consuming and expensive.

With ever-decreasing critical dimensions for microelectronic devices, the design and fabrication for these devices on substrates is becoming or has become increasingly complex. Control of the critical dimensions and process uniformity becomes increasingly more significant. Complex multilayer stacks used to make microelectronic devices involve precise process monitoring of the critical dimensions for the thickness, roughness, stress, density, and potential defects. Process recipes for forming the devices have multiple incremental processes to ensure critical dimensions are maintained. Typically, each incremental process may utilize one or more processing chambers that adds additional time for forming the devices and increases opportunities for defects forming.

As critical dimensions on these devices shrink, past fabrication techniques encounter new hurdles. For example, as the number of layers increase on the multilayer stacks used to make microelectronic devices, film stress and substrate bowing becomes more of an issue. Film deposition and other processing techniques used in forming the devices typically occur one side of the substrate. As the deposited layers build up, they can introduce stress in the substrate that can cause the substrate to undesirably bow. Substrate bowing may cause feature alignment issues in subsequent processing steps resulting in defects.

One solution for correcting substrate bowing is to deposit additional material on the backside and bevel edge of the substrate. The deposited materials on the backside of the wafer counteracts substrate bowing and stress. Conventional processing systems are only suitable for film deposition on either a substrate's backside or bevel edge but not both. These processing systems introduce additional problems, such as additional handling between two or more specialized processing systems, potential exposure to particles, and/or reduction in processing yield.

Therefore, there is a need for an improved method for processing substrate and improve yield in a cost-effective manner.

### SUMMARY

A method and apparatus for performing backside and bevel edge deposition is described herein. Disclosed herein is a processing system. The processing system has an upper chamber body and a lower chamber body defining a processing environment. An upper heater is moveably disposed in the upper chamber body. The upper heater has a moveable support and an upper step formed along an outer perimeter. A lower showerhead is fixedly disposed in the lower chamber body. The lower showerhead includes a top surface configured to support a substrate, a lower step disposed along an outer perimeter. The substrate is configured to extend from the top surface partially over the lower step. Lift pins are disposed in the lower showerhead and configured to extend through the top surface and support the substrate thereon. Gas holes are disposed in a first zone along the top surface and a second zone on the step and configured to independently flow both a process and non-process gas.

A method for performing film deposition on a backside of a substrate is described herein. The method begins by introducing a substrate on a robot blade into a processing volume of a processing chamber. The substrate is raised on lift pins above a lower showerhead. Non-process gas is provided from a heater disposed above the substrate. Process gas is provided through the lower showerhead. Plasma may form on a backside of the substrate using the RF energized parts. The plasma provides energized particles under the raised substrate. The substrate is removed from the processing volume of the processing chamber by the robot blade.

A method for performing bevel edge deposition on a backside of a substrate is described herein. The method begins by introducing a substrate on a robot blade into a processing volume of a processing chamber. The substrate is lowered on lift pins onto a lower showerhead. An upper heater is lowered into toward to the substrate. A non-processing gas is provided through an inner portion of the lower showerhead. Energized particles are provided from a remote plasma source in an outer portion of the lower showerhead. The substrate is raised on the lift pins and removed from the processing chamber.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 illustrates a schematic cross-sectional view of a processing chamber, according to one embodiment.

FIG. 2A illustrates an upper heater for use in the processing chamber of FIG. 1.

FIG. 2B illustrates a plan view of the upper heater shown in FIG. 2A.

FIG. 3A illustrates a lower showerhead for use in the processing chamber of FIG. 1.

FIG. 3B illustrates a plan view of the lower showerhead shown in FIG. 3A.

FIG. 4 is a flow diagram of a method for processing a substrate within the processing chamber of FIG. 1.

FIG. 5 is a flow diagram of another method for processing a substrate within the processing chamber of FIG. 1

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Described herein is a method and apparatus for performing backside and bevel edge deposition in a single processing chamber. The processing chamber is configured to perform both backside and bevel deposition in same chamber. The processing chamber has a switchable ground electrode suitable for changing the plasma density distribution from center high to edge high. The processing chamber addresses substrate handling induced defects while enabling substrate bowing profile control and also provides the capability to flatten the bowed profile. The processing chamber enables higher wafer temperature during backside and bevel deposition for reducing edge defects and the number of processing steps for correcting substrate bowing.

The disclosed processing chamber provides fine adjustment for each lift pin to maintain tight parallelism between upper heater and the substrate for concentric purge and uniform heating. The lift pins for backside deposition and transport are provided at the substrate edge to prevent close bevel contact at the edge. The lift pins retract away from bevel edge to place the substrate on the showerhead for bevel deposition. Plasma “switching” from backside to bevel is provided based on Pressure-Distance effect for improved film formation.

A “substrate” or “substrate surface,” as described herein, generally refers to any substrate surface upon which processing is performed. Processing includes deposition, etching, patterning and other methods utilized during semiconductor processing. A substrate or substrate surface which may be processed also includes dielectric materials such as silicon dioxide, silicon nitride, organosilicates, and carbon doped silicon oxide or nitride materials. In certain embodiments, the substrate or substrate surface includes photoresist materials, hardmask materials, or other films or layers utilized in the patterning of a substrate. The substrate itself is not limited to any particular size or shape. Although the embodiments disclosed herein are generally described with reference to a round 200 mm or 300 mm substrate, other shapes, such as polygonal, squared, rectangular, curved, or otherwise non-circular substrates may be utilized according to the embodiments described herein.

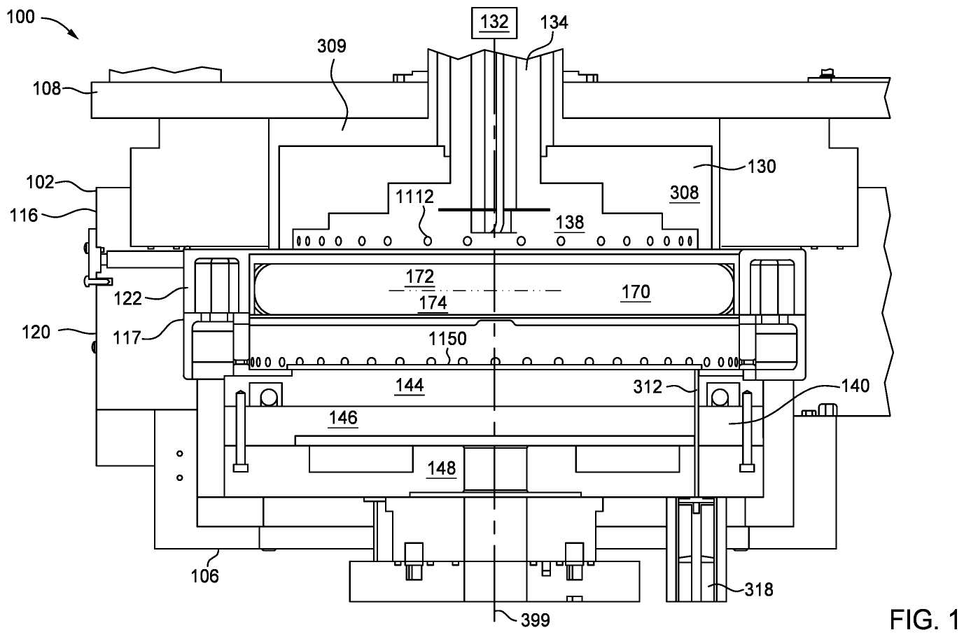

FIG. 1 illustrates a schematic cross-sectional view of a process chamber 100, according to one embodiment. The process chamber 100 is configured to perform backside and bevel edge deposition operations on a substrate 150 in a single processing chamber. However, it is contemplated that other suitably configured processes may benefit from the embodiments described herein.

The process chamber 100 includes a body 102. The body 102 has an upper chamber body 116 coupled to the lower chamber body 120. The body 102 additionally has a lid 108 disposed on the upper chamber body 116. The body 102 has a bottom 106 which is a part of the lower chamber body 120. The bottom 106 of the body 102 is opposite the lid 108. The upper chamber body 116, the lower chamber body 120 and the lid 108 enclose an area defining a processing volume 170. The processing volume 170 has an upper portion 172 and a lower portion 174 disposed below the upper portion 172.

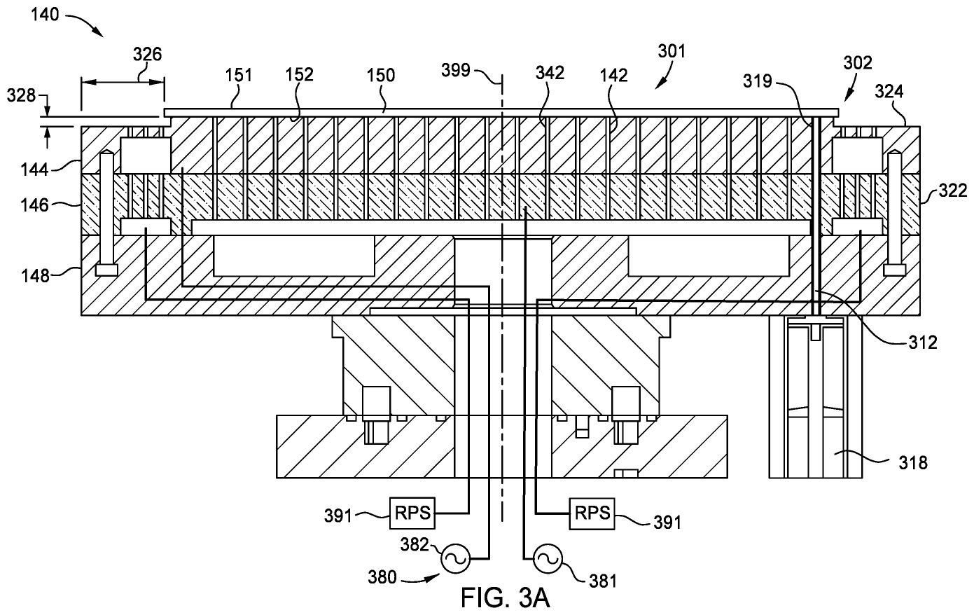

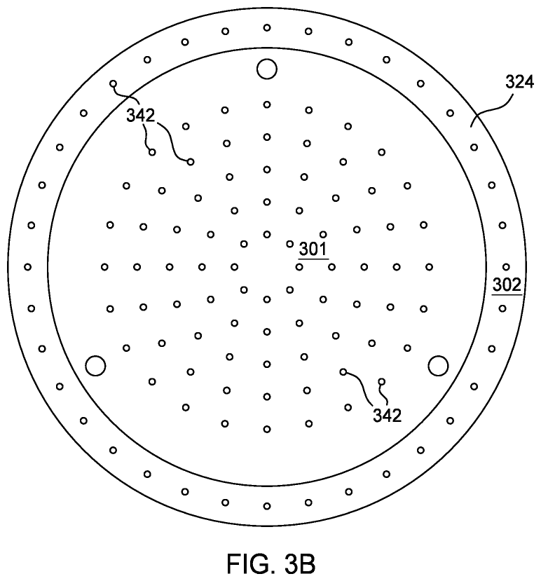

The lower chamber body 120 includes at least one substrate transfer passage 160 disposed therethrough. The transfer passage 160 may have a slit valve door configured to provide access to the process volume 170 by a transfer robot moving the substrate 150 into and out of the process volume 170. The substrate 150 has a top surface 151 and a bottom surface 152, as shown more clearly in FIG. 3A. Features are formed on the top surface 151. All handling, such as with transfer robot, lift pins, chucking, etc., of the substrate 150 is with contact to the bottom surface 152 to prevent damage to the features formed on the top surface. The substrate 150 is loaded into processing chamber 100 with the top surface 151 facing upward toward the lid 108 and may be maintained in that orientation throughout all operations performed by or in processing chamber 100.

A pumping liner 122 may be disposed radially inward of an interior wall 117 of the lower chamber body 120. The pumping liner 122 surrounds the sides of the processing volume 170. The pumping liner 122 includes a plurality of openings connecting an exhaust plenum and the process volume 170. The pumping liner 122 is fluidly coupled to the processing volume 170. The pumping liner 122 is additionally fluidly coupled to a vacuum pump such that gas is removed via the exhaust plenum by the pump. The pumping liner 122 may be formed from ceramic or other suitable material. The pumping liner 122 is configured to remove process gases and other fluids or particles from the processing volume 170.

An edge gas feed 168 is disposed above the pumping liner 122 radially inward of the upper chamber body 116. The edge gas feed 168 is configured to provide a purge gas downward into the processing volume 170. The edge gas feed 168 is directed to the outer edge of the top surface 151 of the substrate 150.

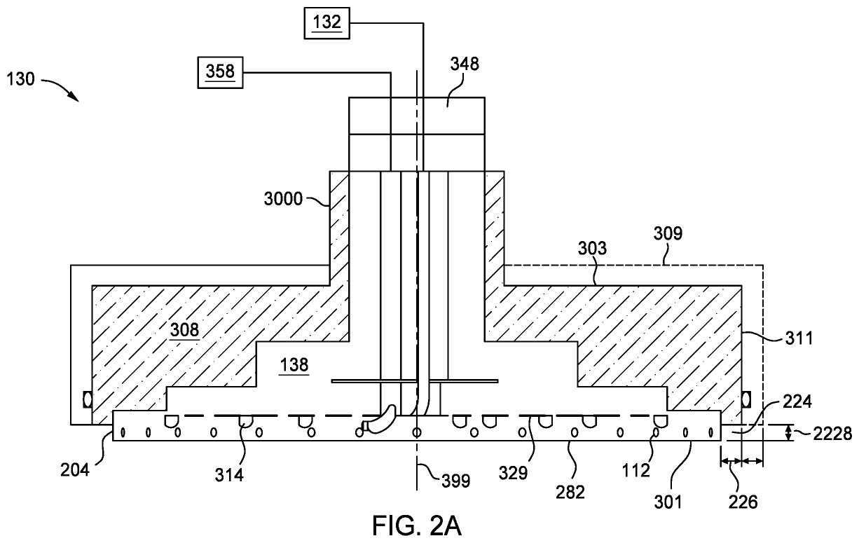

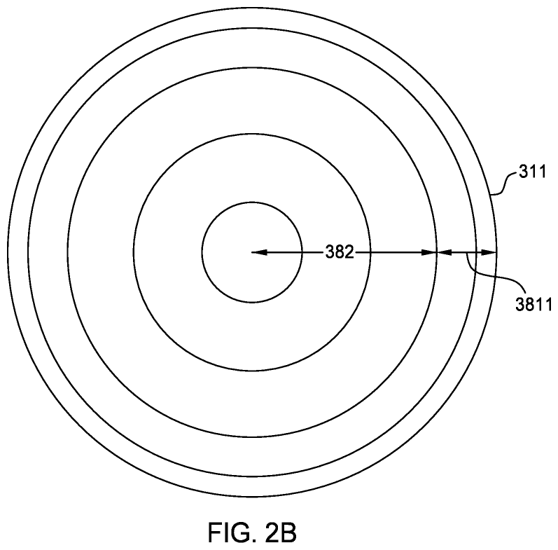

An upper heater 130 is exposed to an upper portion 172 of the process volume 170. The upper heater 130 is coupled to the lid 108. Alternately, the upper heater 130 is coupled to the upper chamber body 116. The upper heater 130 is configured to provide heat to the processing volume 170. The upper heater 130 may have one or more gas holes 112 for providing purge gas or other inert gases into the processing volume 170. The gas holes 112 are coupled to a non-processing gas source 132. The non-processing gas source 132 is introduced into the processing volume 170 adjacent the upper heater 130 to prevent plasma deposition or processing in the upper portion 172 of the processing volume 170 adjacent to upper heater 130. The upper heater 130 will be discussed in greater detail with respect to FIGS. 2A and 2B.

FIG. 2A illustrates the upper heater 130 used in the processing chamber of FIG. 1. FIG. 2B illustrates a plan view of the upper heater 130 shown in FIG. 2A. The upper heater 130 has a body 300. The body 300 has an outer perimeter 311, a process facing surface 282, and a top surface 303 opposite the process facing surface 282.

The body 300 includes a pedestal 138 and a dielectric portion 308. The dielectric portion 308 surrounds the pedestal 138. A grounded shield 309 may optionally surround the dielectric portion 308. The pedestal 138 has one or more heaters 314 disposed therein. The heaters 314 may be arranged in zones, for example, an inner 382 and an outer zone 281, which operate independently of each other. In one example the pedestal 138 is coupled to a power source (not shown) which may make the pedestal RF hot independently in the inner zone 282 and the outer zone 281. The non-processing gas source 132 may provide non-processing gas through the gas holes 112 disposed in either the inner zone 282 or the outer zone 281. Optionally, the gas holes 112 in the outer zone 281 may additionally be coupled to a remote plasma source for providing energized ions in the outer zone 281. In this manner, processing can be made to occur along the bevel edge of the substrate 150.

The upper heater 130 includes a movable support 134. Movable support 134 is disposed through, or attached to, the lid 108. Movable support 134 may be attached to the pedestal 138. Alternately, the movable support 134 is attached to the dielectric portion 308. The movable support 134 is configured to move the upper heater 130 vertically. In FIG. 1, the upper heater 130 is shown in the upper most location, i.e., the movable support 134 is in the raised position. In some processing operations, such as backside deposition, the movable support 134 locates the upper heater 130 in the upper most location. The movable support 134 is additionally configured to place the upper heater 130 in a lower position. In some processing operations, such as bevel edge deposition, the movable support locates the upper heater 130 in the lower most location.

The upper heater 130 has upper step 224 formed through the outer perimeter 311. The upper step 224 has length 226 along the process facing surface 282. The upper step 224 has height 228 along the outer perimeter 311. The length 226 and height 228 are configured to draw the plasma used in an edge deposition operation above the substrate. The length 226 and height 228 are configured to prevent deposition too far along the top surface of the substrate while ensuring the edge of the substrate receives adequate material from the deposition operation. In one example, the height 228 of the upper step 224 is between about 3 mm and about 7 mm. In one example, the length 226 is between about 1 mm and about 7 mm. It has been determined that increasing the length 226 and height 228 of the upper step 224 pulls the plasma from under the substrate 150 up and over the bevel edge of the substrate 150. An upper threshold has also been determined for the size of the length 226 and height 228 of the upper step 224 to prevent the plasma from additionally processing the top surface 151 of the substrate 150.

The upper heater 130 has a plurality of grounds coupled to variable capacitors. The variable capacitors are provided in two or more concentric zones. The variable capacitors enable tuning of plasma in the processing volume 170. For example, during backside deposition, the plasma may be tuned to prevent bevel deposition. In another example, the ground is floating in the upper heater such as during a bevel deposition operation.

The upper heater 130 may be coupled to an RF power source (Not Shown). The RF power source may make the upper heater 130 RF hot for maintaining the plasma in the processing volume 170. The upper heater 130 may have a dual RF zone, such as inner and outer zones. For example, a dielectric sleeve may allow separation of energy in an inner zone and an outer zone. In this manner, the outer zone may be made RF hot independent of the inner zone for maintaining the plasma in along a desired location.

Returning to FIG. 1, a lower showerhead 140 is exposed to the lower portion 174 of the processing volume 170. The lower showerhead 140 is coupled to the lower chamber body 120. The lower showerhead 140 includes a gas distribution plate 144, a blocker plate 146 and a gas box 148. The gas distribution plate 144 is exposed to the processing volume 170. The blocker plate 146 is disposed between the gas distribution plate 144 and the gas box 148. The lower showerhead 140 may have a plurality of gas holes 342, as shown in FIGS. 3A and 3B, for introducing process gas into the processing volume 170. Process gas are introduced into the gas box 148 and then distributed through the gas holes 342 in the gas distribution plate 144 into the processing volume 170. The lower showerhead 140 will be discussed in greater detail with respect to FIGS. 3A and 3B.

FIG. 3A illustrates a lower showerhead 140 for use in the processing chamber of FIG. 1. FIG. 3B illustrates a plan view of the lower showerhead 140 shown in FIG. 3A. The lower showerhead 140 has a top surface 304 along the gas distribution plate 144. The lower showerhead 140 has a center 399 and an outer circumference 322.

A bottom step 324 is formed between the top surface 304 and the outer circumference 322. The lower showerhead 140 is configured to support a substrate 150 on the top surface 304. The bottom step 324 is formed below a location of the top surface 304. The bottom step 324 extends toward the center 399 of the lower showerhead 140 a distance 326 such that a diameter of the top surface 304 is smaller than a diameter of the substrate 150. In this manner, a bevel edge 153 at the outer perimeter of the substrate 150 extends over the bottom step 324. The bottom step 324 has a depth 328 extending into the top surface 304. The distance 326 and depth 328 are configured to maintain the plasma along the outer edge of the substrate 150. The distance 326 and depth 328 are configured to pull deposition under the substrate 150 while ensuring the edge of the substrate receives adequate material from the deposition operation. In one example, the depth 328 of the bottom step 324 is between about 3 mm and about 7 mm. In one example, the distance 326 is between about 1 mm and about 7 mm.

When the substrate 150 is lowered onto the lower showerhead 140, processing of the bevel edge is possible without further processing of the bottom of the substrate 150. It has been determined that increasing the distance 326 and depth 328 of the bottom step 324 pulls the plasma under the bevel edge of the substrate 150 while not processing the bottom of the substrate. An upper threshold has also been determined for the size of the distance 326 and depth 328 of the bottom step 324 to prevent the plasma from remaining under the substrate 150 and minimizing or preventing processing of the bevel edge.

The lower showerhead 140 has lift pins 312. The lift pins 312 are coupled to a lift assembly 318. The lift pins extend through the gas distribution plate 144, the blocker plate 146 and the gas box 148. The lift assembly 318 is disposed below the gas box 148. The lift assembly 318 is configured to move the lift pins 312 vertically between an up and a down position. The lift assembly 318 provides fine adjustment for each lift pin 312. The lift assembly 318 fine adjustment for each lift pin 312 maintains tight parallelism between upper heater 130 and the top surface 151 of the substrate 150. The tight parallelism between upper heater 130 and the top surface 151 of the substrate 150 enhances uniform heating and concentric purge of process gasses.

The lift pins 312 may be disposed in dielectric sleeves 319. In one example, the lift assembly 318 has four lift pins 312. The lift pins 312 are positioned at the outermost portion of the lower showerhead 140. For example, the lift pins 312 may be disposed at the intersection of the top surface 304 and the bottom step 324. The lift pins 312 have a flat in the top surface upon which the substrate edge is supported. The lift pins 312 may be fixed from rotation to minimize abrasion and preventing damage of the substrate edge. In another example, the lift pins 312 may be disposed through the bottom step 324. For example, the lift pins 312 may be placed between about 148 mm and about 149 mm, such as 148.5 mm radius from the center 399 of the lower showerhead 140. This arrangement places the lift pins 312 at an outer edge of the bottom surface 152 of the substrate 150. The lift assembly 318 moves lift pins 312 into a raised position for elevating the substrate 150 above the lower showerhead 140. The lift pins 312 positioned in the raised position allow the substrate 150 to be moved in and out of the processing chamber 100. Additionally, the raised lift pins 312 may elevate the substrate 150 above the lower showerhead 140 for backside processing. The lift pins 312 are configured to lower the substrate 150 and place the bottom surface 152 of the substrate 150 on the top surface 304 of the lower showerhead 140 for bevel edge processing.

The gas holes 142 may be arranged in zones such as inner zone 301 and an outer zone 302. The inner zone 301 may extend along the top surface 304 to the lift pins 312. The outer zone 302 may extend from the lift pins 312 and outward along the bottom step 324. In one example, the lower showerhead 140 has five independent flow zones. The inner zone 301 may be the first zone. The inner zone 301 may be shaped as a small circular area in the center of the lower shower head 140. The outer zone 302 may include four independently flow controlled segments. The four independently flow controlled segments may be equally sized. The flow of gas to each of the five independently flow controlled segments may have their respective flow of gasses incrementally and independently controlled. For example, a first segment of the outer zone 302 may have a higher flow rate than a second segment of the outer zone 302 while the first segment additionally has a lower flow rate than a third segment outer zone 302. During bevel deposition, the 5 zones may provide inert or oxygen or nitrogen gas to purge the backside of the substrate 150. Zonal flow may additionally be used to tune the thickness profile of the material deposited on the substrate's bevel edge during a bevel edge deposition process. The different flow rates of process gases in each of the independently flow controlled segments enable zonal distribution of deposited material layer thickness and therefore reduces the stress of the deposited film on the wafer backside during a backside deposition process.

A remote plasma source (RPS) 391 energizes a process gas to be supplied to the gas holes 142 disposed in the inner zone 301. A remote plasma source (RPS) 392 may energize a process gas to be supplied independently to the outer zone 302 and the inner zone 301. The gas holes 142 in the inner zone 301 are configured to operate independently from the gas holes 142 in the outer zone 302. In this manner, backside processing operations and bevel edge processing operations on the substrate 150 can be performed independently in the outer zone 302 and the inner zone 301. Additionally, the RPS 391/391 may also be used for chamber cleaning.

The lower showerhead 140 may be coupled to an RF power source 380. The RF power source 380 may make the lower showerhead 140 RF hot for maintaining the plasma in the processing volume 170. The lower showerhead 140 may have a dual RF zone, such as inner and outer zones. For example, the dielectric sleeve 319 may allow separation of energy in the inner zone 301 and the outer zone 302. An inner RF generator 381 may be coupled to the inner zone 301. An outer RF generator 382 may be coupled to the outer zone 302. In this manner, the outer zone 302 may be made RF hot independent of the inner zone 301. In one example, the outer zone 302 is RF hot while the inner zone 301 is RF cold. In another example, the lift pins 312 are RF hot.

In one example process gas is applied exclusively to the outer zone 302 while no process gas is applied to the inner zone 301. RF power may be applied exclusively to the outer zone 302 such that plasma is formed and maintained along the bevel edge 153 of the substrate 150. In such an example, the bevel edge 153 of the substrate 150 may be processed exclusively of the bottom surface 152 of the substrate 150.

An edge heater 392 may be disposed in the lower showerhead 140. The edge heater 392 heats the area of the bottom step 324. The edge heater 392 provides better film control at the bevel edge 153 of the substrate 150.

A power source 358 and a motion apparatus 348 are also coupled to the movable support 134. The power source 358 may be an AC or a DC power source. The power source 358 is configured to supply power to the motion apparatus 348 and/or heating devices 329 within the upper heater 130. The motion apparatus 348 is configured to enable movement of the upper heater 130, such as raising or lowering the upper heater 130.

The above-described processing chamber 100 can be controlled by a processor-based system controller such as controller 178. For example, the controller 178 may be configured to control flow of various gases via the gas sources and coordinate plasma generation and flows within the processing chamber 100. The controller 178 may also be configured to control all aspects of electric field generation within the processing chamber 100 by modulating and controlling application of voltages to one or more of the components of the showerhead and heater to generate an electric field within the process volume 170. The controller 178 further operates to control various stages of a substrate process sequence.

The controller 178 includes a programmable central processing unit (CPU) 192 that is operable with a memory 194 and support circuits 196, an input control unit, and a display unit (not shown), such as power supplies, clocks, cache, input/output (I/O) circuits, and the like, coupled to the various components of the processing chamber 100 to facilitate control of the substrate processing. The controller 178 also includes hardware for monitoring substrate processing through sensors in the processing chamber 100, including sensors monitoring flow, RF power, voltage potential and the like. Other sensors that measure system parameters such as substrate temperature, chamber atmosphere pressure and the like, may also provide information to the controller 178.

To facilitate control of the processing chamber 100 and associated plasma and electric field formation processes, the CPU 192 may be one of any form of general purpose computer processor that can be used in an industrial setting, such as a programmable logic controller (PLC), for controlling various chambers and sub-processors. The memory 194 is coupled to the CPU 192 and the memory 194 is non-transitory and may be one or more of readily available memory such as random access memory (RAM), read only memory (ROM), floppy disk drive, hard disk, or any other form of digital storage, local or remote. Support circuits 196 are coupled to the CPU 192 for supporting the processor in a conventional manner. The plasma and electric field formation and other processes are generally stored in the memory 194, typically as a software routine. The software routine may also be stored and/or executed by a second CPU (not shown) that is remotely located from the hardware being controlled by the CPU 192.

The memory 194 may be in the form of a computer-readable storage media that contains instructions, that when executed by the CPU 192, facilitates the operation of the processing chamber 100. The instructions in the memory 194 may be in the form of a program product such as a program that implements the method of the present disclosure. The program code may conform to any one of a number of different programming languages. In one example, the disclosure may be implemented as a program product stored on computer-readable storage media for use with a computer system. The program(s) of the program product define functions of the embodiments (including the methods described herein).

In certain embodiments, the program(s) embody machine learning capabilities. Various data features include process parameters such as processing times, temperatures, pressures, voltages, polarities, powers, gas species, precursor flow rates, and the like. Relationships between the features are identified and defined to enable analysis by a machine learning algorithm to ingest data and adapt processes being performed by the processing chamber 100. The machine learning algorithms may employ supervised learning or unsupervised learning techniques. Examples of machine learning algorithms embodied by the program include, but are not limited to, linear regression, logistic regression, decision tree, state vector machine, neural network, naïve Bayes, k-nearest neighbors, K-Means, random forest, dimensionality reduction algorithms, and gradient boosting algorithms, among others. In one example, the machine learning algorithm is utilized to modulate RF power and precursor gas flow to form a plasma and then facilitate maintenance of a low ion density plasma which includes a greater concentration of radicals than ions. The formation of charges species in this manner may be refined and improved by identifying constituents of the charged species cloud (e.g. radicals and/or ions) and modifying chamber process or apparatus characteristics to form and maintain a charged species cloud which exhibits desirable characteristics as an electric field coupling medium between the ion blocking plate 114 and the upper heater 130.

Illustrative computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure.

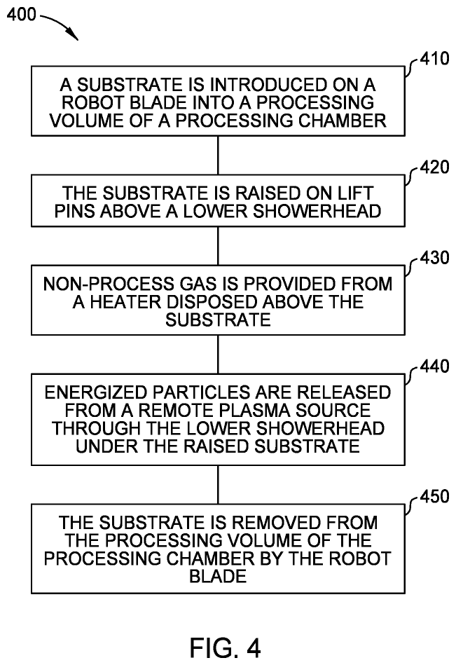

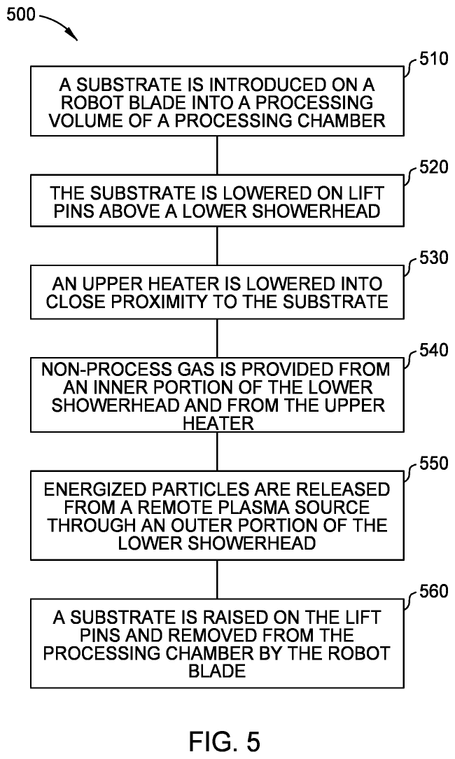

The controller 178 may be configured to perform operations for both backside and bevel edge deposition in the same processing chamber 100. For example, the controller 178 is configured to perform the operations described below with respect to FIGS. 4 and 5.

FIG. 4 is a flow diagram illustrating a method 400 for processing a substrate within the processing chamber of FIG. 1, according to one embodiment. Method 400 describes a sequence of operations for backside deposition on a substrate. The method 400 begins at operation 410, where a substrate 150 is introduced into the processing volume 170 of the processing chamber 100 on a robot blade. The substrate 150 is oriented and maintained with the device side facing up.

At operation 420, substrate is raised on lift pins above a lower showerhead. The lower showerhead has an inner zone extending between the center of the lower showerhead and the lift pins. The lower showerhead has an outer zone extending from the lift pins to an outer perimeter of the lower showerhead.

At operation 430, non-process gas is provided from a heater disposed above the substrate. The non-processing gas maintains the plasma along the backside of the substrate 150 by using the non-processing gas to prevent the energized particles from entering the upper portion of the processing volume.

At operation 440, a plasma source, or remote plasma source (RPS), energizes particles to provide an active plasma between the lower showerhead and the raised substrate. The active plasma may form in a “pancake” like shape below the substrate for backside deposition. In some examples, the “pancake” like plasma may extend over the bevel edge and provide material deposition along the bevel edge. The lower showerhead may additionally be coupled to a non-process gas source. The RPS may provide the energized particles independently to the inner zone and the outer zone. In one example, the RPS provides energized particles to both the inner zone and the outer zone. In another example, the RPS provides energized particles to only the outer zone, and the inner zone is provided with non-process gas from the non-process gas source.

At operation 450, the substrate 150 is removed from the processing volume 170 of the processing chamber 100 on the robot blade. Alternately, the substrate 150 may be further processed in the processing chamber 100. For example, the processing chamber 100 may deposit material on the bevel edge of the substrate 150. The substrate 150 is oriented in the same direction for the backside deposition and the bevel edge deposition. FIG. 5 describes a method 500 bevel edge deposition for the substrate 150.

FIG. 5 is a flow diagram illustrating a method 500 for processing a substrate within the processing chamber of FIG. 1, according to one embodiment. Method 500 describes a sequence of operations for bevel edge deposition on a substrate. The method 500 begins at operation 510, where a substrate 150 is introduced into the processing volume 170 of the processing chamber 100 on a robot blade.

At operation 520, the substrate 150 is lowered on lift pins disposed in a lower showerhead. The substrate 150 is lowered onto the top surface of the lower showerhead and off the lift pins. The substrate 150 may sit at the outer rim of the lower showerhead and disengaged from the lift pins. The lower showerhead may have a step disposed along an outer periphery and into the top surface of the lower showerhead. The substrate edge may extend over the step such that the substrate is not in contact with the lower showerhead or step along the outer edge of the substrate. Alternately, the substrate 150 may be continuously supported by the lift pins above the lower showerhead.

At operation 530, the upper heater is lowered into close proximity to the substrate 150. For example, the upper heater may be lowered to between about 0.5 mm to about 1.0 mm of the substrate. The upper heater may have zones of heaters and a step along the outer periphery. The step is sized to draw plasma over the substrate bevel edge without drawing the plasma onto the top surfaces where devices are present.

At operation 540, non-processing gas is provided through an inner portion of the lower showerhead and from the upper heater. The inner portion may be surrounded by an outer portion.

At operation 550, a plasma source provides energized particles in an outer portion of the lower showerhead. In one example, a remote plasma source provides energized particles. In another example, the gases are energized in the showerhead or upon leaving the showerhead to provide the energized particles. The non-processing gas prevents the energized particles from impacting the top of the substrate and moves processing outward to the bevel edge. The step in the upper heater shapes the plasma and further draws the energized particles along the bevel edge. The processing is confined by the upper step and lower step along the bevel edge. This results in a “donut” like shape for the plasma which is used for bevel edge deposition.

At operation 560, the substrate is raised on the lift pins and removed from the processing chamber. The substrate 150 is oriented in the same direction with the device side facing the upper heater.

It should be appreciated that the operations described in method 400 and method 500 may be performed back to back in the same properly configured processing chamber, such as processing chamber 100. There is no requirement for one method to be performed before the other method. It should be appreciated that material deposited on the backside of the substrate 150 during backside deposition may form an indent in the location where the lift pins 312 are in contact with the substrate 150 during method 400. However, the bevel edge deposition operation disclosed in method 500 provides the substrate 150 on the lower showerhead 140 with the area of the substrate having the indent from contact with the lift pins 312 exposed over the step 352 and subject to deposition. Thus, the indents in the backside of the substrate may be beneficially removed during the bevel edge deposition. Thus, the quality of the substrate film on the backside may benefit from performing the backside deposition followed by the bevel edge deposition.

Advantageously, the apparatus provides a single chamber design for performing backside and bevel edge deposition. The single chamber reduces the complexity and excess handling of the substrate for minimizing defects and improving throughput. The chamber is configured to correct substrate bowing in order to ensure film integrity and alignment when forming devices on the top surface in subsequent operations. Additionally, the apparatus and method decreases processing steps and time for reducing the cost of device fabrication.

While the foregoing is directed to embodiments of the present disclosure, other and further embodiments of the disclosure may be devised without departing from the basic scope thereof, and the scope thereof is determined by the claims that follow.

What is claimed is:

1. A processing system comprising:
a chamber body comprising:
an upper chamber body having a lid; and
a lower chamber body having a bottom, wherein the upper chamber body and lower chamber body enclose an area defining a processing environment;
an upper heater moveably disposed in the upper chamber body, the upper heater comprising:
a heater body have two or more heaters disposed in concentric zones;
a moveable support attached to the heater body; and
an upper step formed in the heater body along an outer perimeter and exposed to the processing environment; and
a lower showerhead fixedly disposed in the lower chamber body, the lower showerhead comprising:
a showerhead body having a top surface configured to support a substrate, the showerhead body having a lower step disposed along an outer perimeter, wherein the substrate is configured to extend from the top surface partially over the lower step;
lift pins disposed in the showerhead body configured to extend through the top surface and support the substrate thereon; and
gas holes disposed through the showerhead body in a first zone along the top surface and a second zone on the lower step, the gas holes configured to independently flow both a process and non-process gas in the first zone and the second zone, wherein the processing system is configured to perform deposition on a backside and bevel edge of the substrate.

2. The processing system of claim 1 wherein the upper step further comprises:
a height between about 3 mm and about 7 mm; and
a length between about 1 mm and about 7 mm.

3. The processing system of claim 1, further comprising:
a remote plasma source (RPS) coupled to the gas holes in the lower showerhead; and
a non-process gas source, wherein the RPS and the non-process gas source are fluidly coupled to the gas holes.

4. The processing system of claim 1, wherein the lift pins are positioned between about 148 mm and about 149 mm from a center of the lower showerhead.

5. The processing system of claim 4, wherein the lift pins are positioned about 148.5 mm from the center of the lower showerhead.

6. The processing system of claim 1, wherein the lower showerhead has one or more radio frequency (RF) power sources with an inner zone and an outer zone and a dielectric sleeve which allows separation of energy in the inner zone and the outer zone.

7. A method for film deposition on a backside of a substrate comprising:
introducing a substrate on a robot blade into a processing volume of a processing chamber;
raising the substrate on lift pins above a lower showerhead;
providing non-process gas from a heater disposed above the substrate;
releasing energized particles from a remote plasma source through the lower showerhead under the raised substrate; and
removing the substrate from the processing volume of the processing chamber by the robot blade.

8. The method of claim 7, wherein the substrate is oriented and maintained with a device side facing up.

9. The method of claim 8, wherein the lift pins are positioned between about 148 mm and about 149 mm from a center of the lower showerhead.

10. The method of claim 9, wherein the lower showerhead has an inner zone extending between a center of the lower showerhead and the lift pins, and the lower showerhead has an outer zone extending from the lift pins to an outer perimeter of the lower showerhead.

11. The method of claim 9, wherein the non-process gas is configured to maintain plasma along the backside of the substrate by preventing the energized particles from entering into an upper portion of the processing volume.

12. The method of claim 9, wherein the lower showerhead has an inner zone and an outer zone, and the remote plasma source provides the energized particles independently to the inner zone and the outer zone.

13. The method of claim 12, wherein the remote plasma source provides the energized particles to only the outer zone, and the inner zone is provided with non-process gas from a non-process gas source.

14. A method for bevel edge deposition on a substrate comprising:
introducing a substrate into a processing volume of a processing chamber on a robot blade;
lowering the substrate on lift pins onto a lower showerhead;
lowering an upper heater towards the substrate;
providing a non-processing gas through an inner portion of the lower showerhead;
providing energized particles from a remote plasma source in an outer portion of the lower showerhead;
raising the substrate on the lift pins; and
removing the substrate from the processing chamber.

15. The method of claim 14, wherein the substrate is oriented and maintained with a device side facing up.

16. The method of claim 15, wherein the lower showerhead has a lower step disposed along an outer periphery and into a top surface of the lower showerhead, and an edge of the substrate extends over the lower step such that the substrate is not in contact with the lower showerhead or step along an outer edge of the substrate.

17. The method of claim 15, wherein the upper heater has zones of heaters and an upper step along an outer periphery of the upper heater.

18. The method of claim 17, wherein the upper step is sized to draw plasma over a bevel edge of the substrate without drawing the plasma onto a top surface of the substrate where devices are present.

19. The method of claim 17, wherein the upper step has a depth between about 3 mm and about 7 mm and a length between about 1 mm and about 7 mm.

20. The method of claim 15 further comprising:
raising the substrate on lift pins above a lower showerhead;
providing non-process gas from a heater disposed above the substrate; and
releasing energized particles from a remote plasma source through the lower showerhead under the raised substrate for a backside deposition.
